(19) United States
(12) Patent Application Publication
(10) Pub. No.: US 2007/0224775 A1
(43) Pub. Date: Sep. 27, 2007

(54) Trench isolation structure having an expanded portion thereof

(76) Inventor: Nick Lindert, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/390,921

(22) Filed: Mar. 27, 2006

(51) Int. Cl. H01L 21/76

(52) U.S. Cl. 438/424

(57) ABSTRACT

Embodiments of the present invention relate to the fabrication of isolation structures within a microelectronic substrate for microelectronic devices, wherein the design of the isolation structures reduce or substantially eliminate the formation of surface voids within a dielectric material of the isolation structures. These surface voids are reduced or avoided by providing an expanded portion of the trench structure or chamber substantially opposing an opening of the trench structure.

### BACKGROUND OF THE INVENTION

1. Field of the Invention

An embodiment of the present invention relates to integrated circuit manufacturing. In particular, embodiments of the present invention relate to providing isolation structures between integrated circuit components.

2. State of the Art

Microelectronic integrated circuits are formed by chemically and physically forming circuit components in and on a microelectronic substrate, such as a silicon wafer. These circuit components are generally conductive and may be of different conductivity types. Thus, when forming such circuit components, it is essential that they are electrically isolated from one another, wherein electrical communication between the isolated circuit components is achieved through discrete electrical traces.

One isolation scheme used in manufacturing integrated circuits is shallow trench isolation (STI), in which shallow dielectric filled trenches electrically separate neighboring circuit components, such as transistors. For example, STI is a preferred isolation structure for 0.25 micron and smaller topographies, as will be understood to those skilled in the art.

As shown in FIG. 11, to form an STI structure, a microelectronic substrate 202, such as a silicon-containing substrate, is provided. The microelectronic substrate 202 may have a pad oxide 204 formed thereon, which may be used in the subsequent fabrication of transistors, and a stop layer 206, such as silicon nitride, which is used in a subsequent processing step. As shown in FIG. 12, a channel or trench 208 is formed in the substrate 202 through the pad oxide 204 and the stop layer 206. The trench 208 may be made by any technique known in the art, including but not limited to lithography, ion milling, and laser ablation.

As shown in FIG. 13, a trench sidewall spacer 212 is then formed in the trench 208 (see FIG. 12). The trench sidewall spacer 212 may be formed by any technique known in the art including, but not limited to, physical vapor deposition, chemical vapor deposition, and atomic layer deposition. When the microelectronic substrate 202 contains silicon, the trench sidewall spacer 212 may be formed by heating the microelectronic substrate 202 in the presence of oxygen, such that a layer of silicon oxide is formed as the trench sidewall spacer 212.

As shown in FIG. 14, the trench 208 (see FIG. 12) is substantially filled with a dielectric material 214. Any dielectric material 214 not residing within the trench 208 (see FIG. 12) is then removed, such as by etching or planarization by chemical mechanical polishing, as shown in FIG. 15. The stop layer 206 acts as a barrier and/or hard stop, if chemical mechanical polishing is used, or as a etch stop, if etching is used. The stop layer 206 is then removed to form the isolation structure 218, as shown in FIG. 16, wherein the pad oxide 204 acts as a stop layer. It is noted that the removal of the stop layer 206 also removes a majority of the dielectric material 214 above the microelectronic substrate 202.

Higher performance, lower cost, increased miniaturization of integrated circuit components, and greater packaging density of integrated circuits are ongoing goals of the microelectronic industry. As these goals are achieved, the microelectronic components become smaller, which includes reducing the average width 222 of the trench 208 (see FIG. 17). Although reducing the trench width 222 is desirable from a performance and cost perspective, it causes the aspect ratio (trench depth 224 to trench width 222) to become too high and introduces unpredictable isolation voids, as shown in FIG. 17. These voids 226 are formed during the deposition of the dielectric material 214 after the processing step of FIG. 13. Furthermore, narrow-Z transistors, which are becoming more and more critical with each generation, exhibit significantly better performance if the trenches are made smaller and more of the real estate is used for the transistor diffusion.

Any dielectric material 214 not residing within the trench 208 is then removed, such as by etching or planarization by chemical mechanical polishing, as shown in FIG. 18. The stop layer 206 acts as a barrier and/or hard stop. The stop layer 206 is then removed to form an isolation structure 228, as shown in FIG. 19. It is noted that the removal of the stop layer 206 also removes a majority of the dielectric material 214 above the microelectronic substrate 202.

As shown in FIG. 20, generally, the higher the aspect ratio of the trench 208 (see FIG. 17), the higher the tendency for the formation of voids 226 (the aspect ratio decreases from left to right in FIG. 20). As will be understood by those skilled in the art, increasing the angle of the trench side has the same effect (i.e., the more vertical the sidewall, the more the trench is prone to voiding in the dielectric material). It is, of course, understood that such voids 226 can be prevented if the trench depth 224 is decreased in proportion with the trench width 222. However, decreasing the trench depth 224 causes excessive isolation current leakage.

As shown in FIG. 21, voids 226 in the isolation structure 228 can surface (i.e., form an opening in the dielectric material 214) during the deposition of the dielectric material 214 or during subsequent processes. As will be understood by those skilled in the art, this can result in an uneven surface topography for subsequent processing steps and can result in shorting between transistor nodes, if a conducting material fills the void 226.

Therefore, it would be advantageous to develop trench structures that will provide trench width reduction while reducing or substantially eliminating the formation of surface voids within a trench isolation structure, while still providing the necessary electrical isolation.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 illustrates a side cross-sectional view of the microelectronic substrate having a pad oxide and a stop layer formed thereon, according to the present invention;

FIG. 2 illustrates a side cross-sectional view of a trench formed in the microelectronic substrate of FIG. 1, according to the present invention;

FIG. 3 illustrates a side cross-sectional view of a trench sidewall spacer formed in the trench of FIG. 2, according to the present invention;

FIG. 4 illustrates a side cross-sectional view of a portion of trench sidewall spacer abutting the bottom of the trench having been removed to expose the microelectronic substrate, according to the present invention;

FIG. 5 illustrates a side cross-sectional view of a chamber formed in the microelectronic substrate of FIG. 4, according to the present invention;

FIG. 6 illustrates a side cross-sectional micrograph of a chamber formed in the microelectronic substrate through the opening in the trench sidewall layer of FIG. 4, according to the present invention;

FIG. 7 illustrates a side cross-sectional view of filing the trench of FIG. 5 with a dielectric material, according to the present invention;

FIG. 8 illustrates a side cross-sectional view of removing the dielectric material from the stop layer, according to the present invention;

FIG. 9 illustrates a side cross-sectional view of removing the stop layer to the pad oxide, thereby forming an isolation structure, according to the present invention;

FIG. 10 illustrates a side cross-sectional view of an isolation structure having a void within the chamber area thereof, according to the present invention;

FIG. 11 illustrates a side cross-sectional view of the microelectronic substrate having a pad oxide and a stop layer formed thereon, as known in the art;

FIG. 12 illustrates a side cross-sectional view of a trench formed in the microelectronic substrate of FIG. 11, as known in the art;

FIG. 13 illustrates a side cross-sectional view of a trench sidewall spacer formed in the trench of FIG. 12, as known in the art;

FIG. 14 illustrates a side cross-sectional view of filing the trench of FIG. 13 with a dielectric material, as known in the art;

FIG. 15 illustrates a side cross-sectional view of removing the dielectric material from the stop layer, as known in the art;

FIG. 16 illustrates a side cross-sectional view of removing the stop layer to the pad oxide thereby forming an isolation structure, as known in the art;

FIG. 17 illustrates a side cross-sectional view of filing a trench of FIG. 13 with a dielectric material and a void formed in the dielectric material, as known in the art;

FIG. 18 illustrates a side cross-sectional view of removing the dielectric material from the stop layer, as known in the art;

FIG. 19 illustrates a side cross-sectional view of removing the stop layer to the pad oxide thereby forming an isolation structure, as known in the art;

FIG. 20 is a side cross-sectional micrograph of a dielectric filled trenches having a variety aspect ratios, as known in the art; and

FIG. 21 is a side cross-sectional view of a void which has formed an opening in dielectric material, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Embodiments of the present invention relate to the fabrication of isolation structures within a microelectronic substrate for microelectronic devices, wherein the design of the isolation structures reduce or substantially eliminate the formation of surface voids within a dielectric material of the isolation structures. Surface voids are reduced or avoided by providing a chamber or expanded portion of the trench structure substantially opposing an opening of the trench structure.

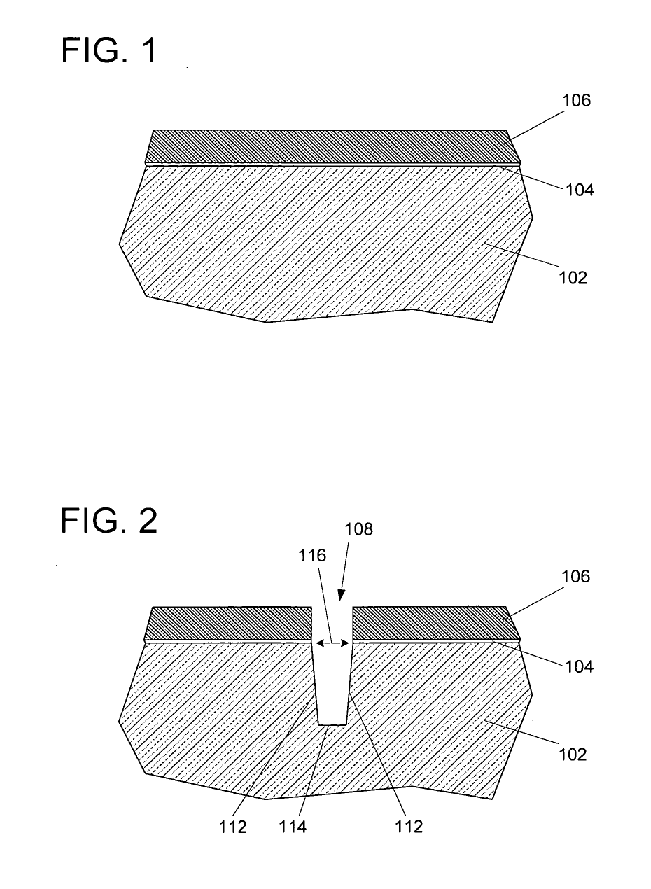

As shown in FIG. 1, to form an isolation structure, a microelectronic substrate 102, which may comprise materials such as silicon, silicon-on insulator, germanium, indium antimonide, lead telluride, indium arsenide, indium phosphide, gallium arsenide, or gallium antimonide, is provided. Although several examples of materials from which the microelectronic substrate 102 may be formed are described here, any material that may serve as a foundation upon which a microelectronic device may be built falls within the spirit and scope of the present invention. The microelectronic substrate 102 may have a pad oxide 104 formed thereon, which may be used in the subsequent fabrication of transistors, and a stop layer 106, such as silicon nitride, which is used in a subsequent processing step.

As shown in FIG. 2, a channel or trench 108 is formed in the microelectronic substrate 102 through the pad oxide 104 and the stop layer 106. The trench 108 comprises at least one sidewall 112 and a bottom 114 (which opposes an opening 116 of the trench in the microelectronic substrate 102). The trench 108 may be made by any technique known in the art, including but not limited to isotropic lithography, ion milling, and laser ablation.

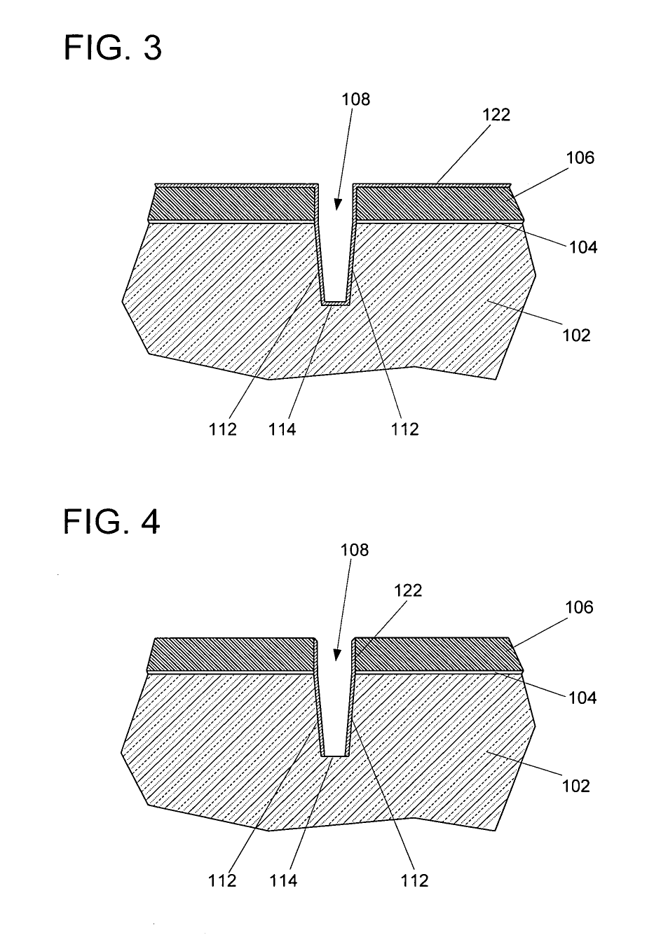

As shown in FIG. 3, a trench sidewall spacer 122 is then formed in the trench 108 substantially abutting the trench sidewalls 112 and the trench bottom 114. The trench sidewall spacer 122 may be formed by any technique known in the art including, but not limited to, physical vapor deposition, chemical vapor deposition, and atomic layer deposition. When the microelectronic substrate 102 contains silicon, the trench sidewall spacer 122 may be formed by heating the microelectronic substrate 102 in the presence of oxygen, such that a layer of silicon oxide is formed as the trench sidewall spacer 122 (abutting only the trench sidewalls 112 and trench bottom 114).

A portion of the trench sidewall spacer 122 abutting the trench bottom 114 is then substantially removed, as shown in FIG. 4, to expose the microelectronic substrate 102. The portion of the trench sidewall spacer 122 can be removed by any means known in the art, preferably as an anisotropic etch. For example, with a trench sidewall spacer 122 comprising silicon oxide, the etch may be a plasma etch employing at least one fluorocarbon containing gas as the etching precursor material, as will be understood to those skilled in the art.

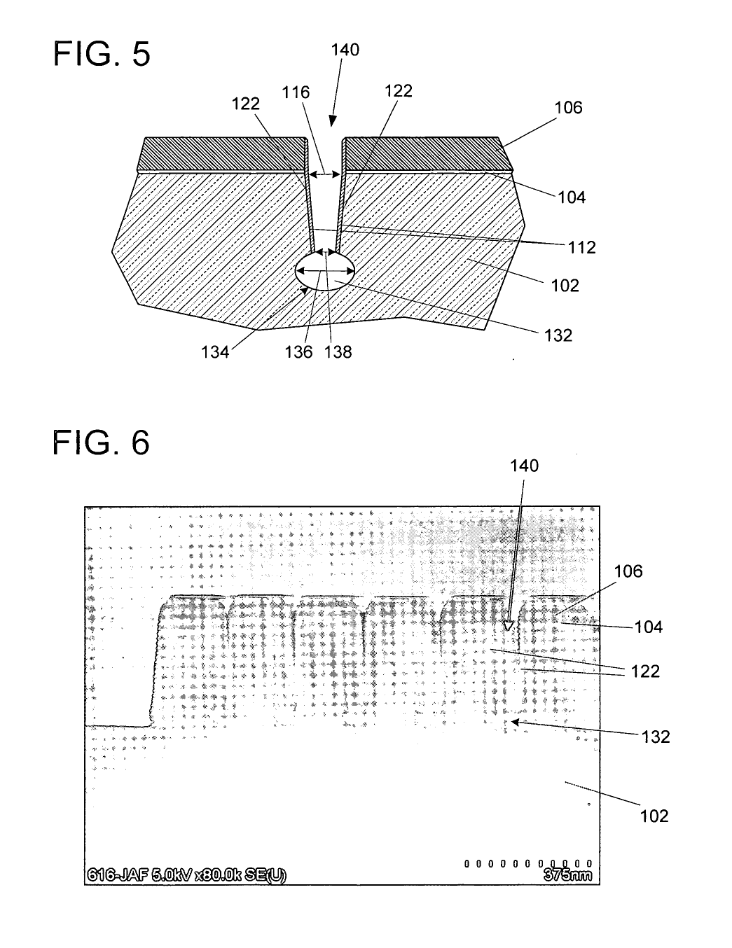

The exposed portion of the microelectronic substrate 102 within the trench 108 is then etched to form a chamber 132 in the microelectronic substrate 102, as shown in FIGS. 5 and 6. The remaining trench sidewall spacer 122 protects the trench sidewalls 112 such that the chamber 132 forms from the trench bottom 114. The trench 108 and the chamber 132 will be hereinafter collectively referred to an expanded bottom trench 140. The chamber 132 of the expanded bottom trench 140 preferably has a substantially arcuate shaped portion 134 opposing the trench opening 116. In one embodiment, the chamber width 136 is greater than the trench bottom width 138.

With a silicon-containing microelectronic substrate 102, the chamber 132 may be formed with a selective isotropic silicon etch, such as a selective wet etch or a plasma etch using NF₃ or SF₆ as precursors, as will be known to those skilled in the art. In one embodiment, as shown in FIG. 6, the etch is achieved with an isotropic plasma etch with SF₆ for the initial oxide breakthrough etch at room temperature followed by a plasma etch with NF₃ for the formation of the substantially arcuate shaped portion 134, also at room temperature.

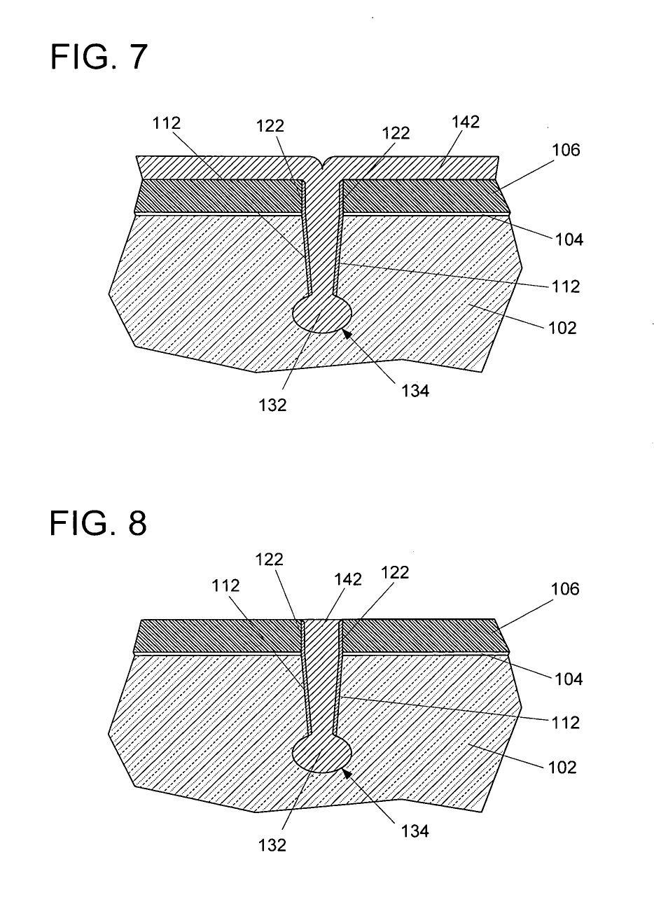

As shown in FIG. 7, the trench 108 (see FIG. 5) is substantially filled with a dielectric material 142, such as silicon dioxide. In one embodiment, the dielectric material is deposited with a high density plasma chemical vapor deposition at about 750 degrees Celsius with silane (SiH₄) and oxygen (O₂) to form silicon dioxide (SiO₂). High density plasma chemical vapor deposition is a simultaneous deposition and sputter process which allows for effective filling, as the material builds up around structure corners from the deposition, the sputtering tears the build-up down.

The substantially arcuate shaped portion 134 of the chamber 132 allows the dielectric material 142 to fill from the substantially arcuate shaped portion 134 and through to the trench opening 116 (see FIG. 5) with a substantially V-shaped or U-shaped cross-sectional profile, which reduces or substantially eliminates the likelihood of forming a void. As such, this allows for a small trench width at the trench opening 116, which, in turn, allows for a greater available area on the microelectronic substrate 102 for use as active areas for subsequently fabricated transistors, as will be understood to those skilled in the art.

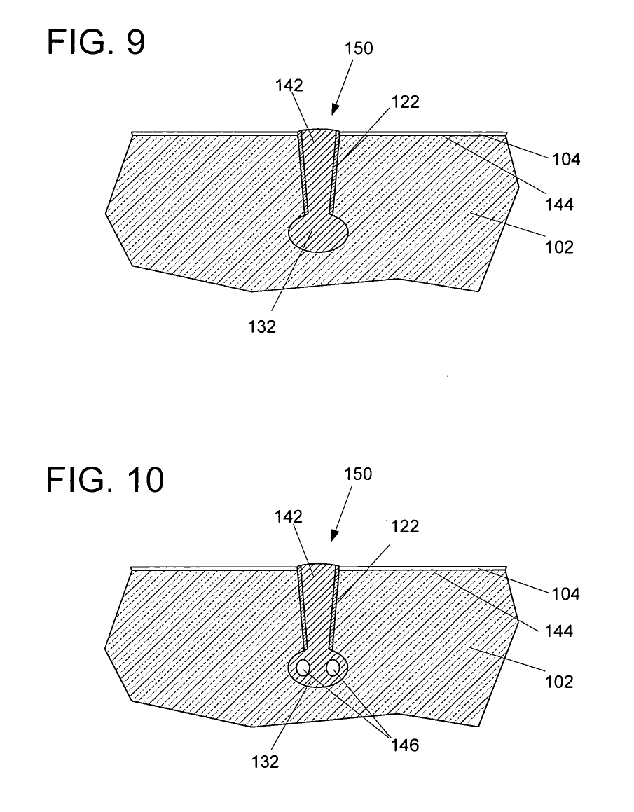

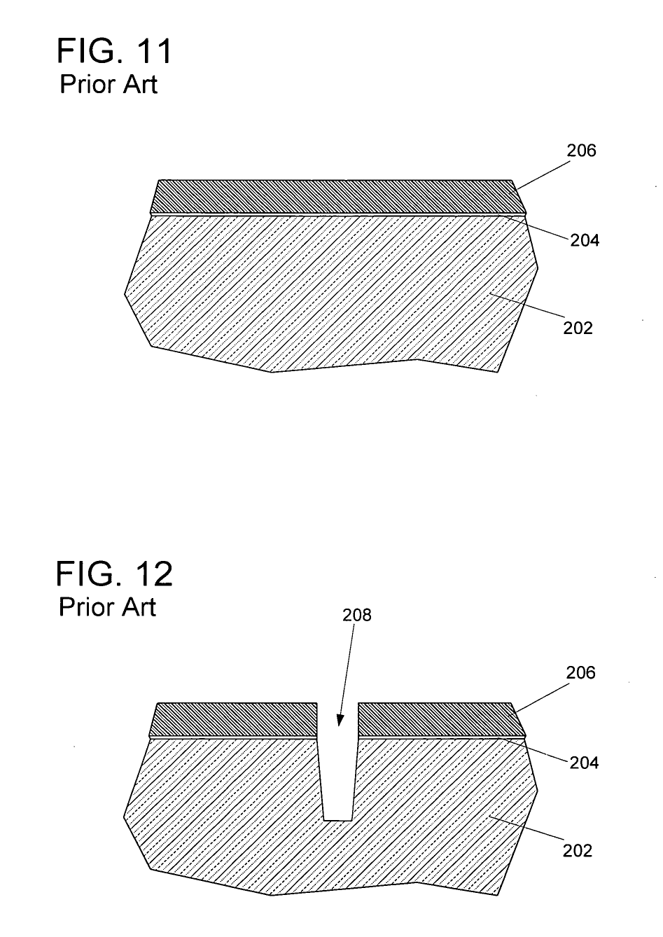

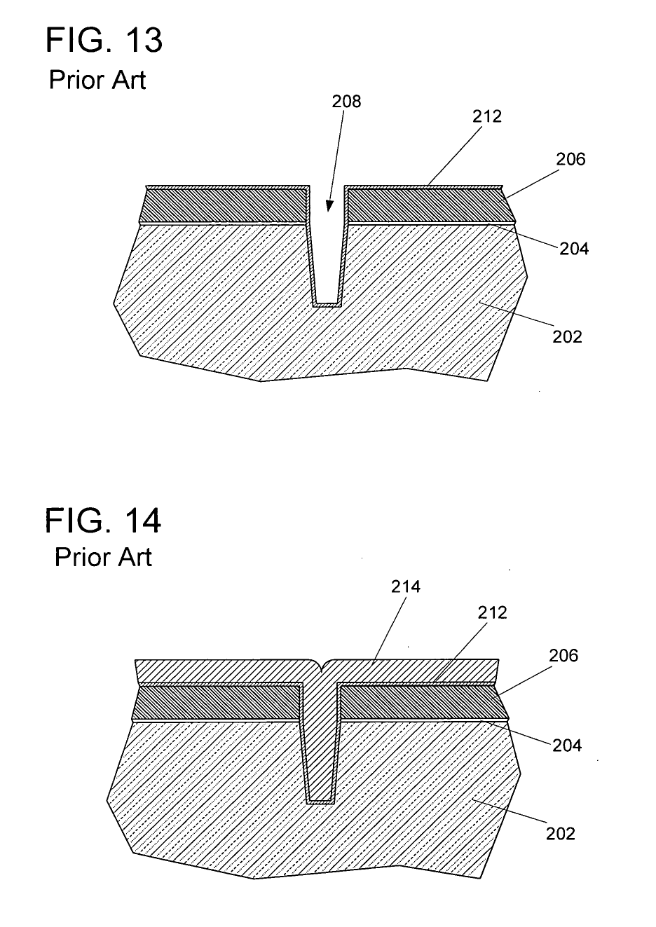

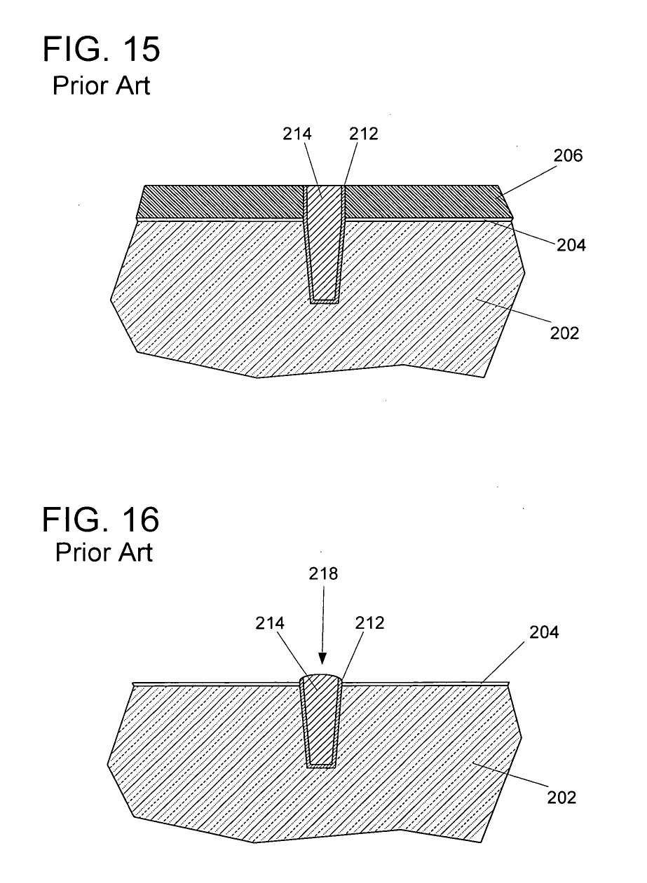

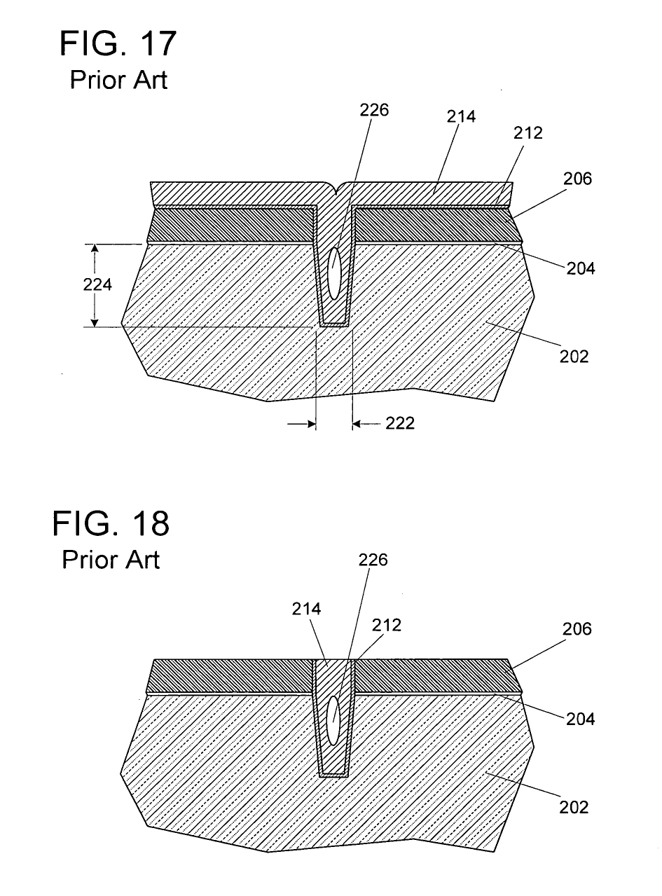

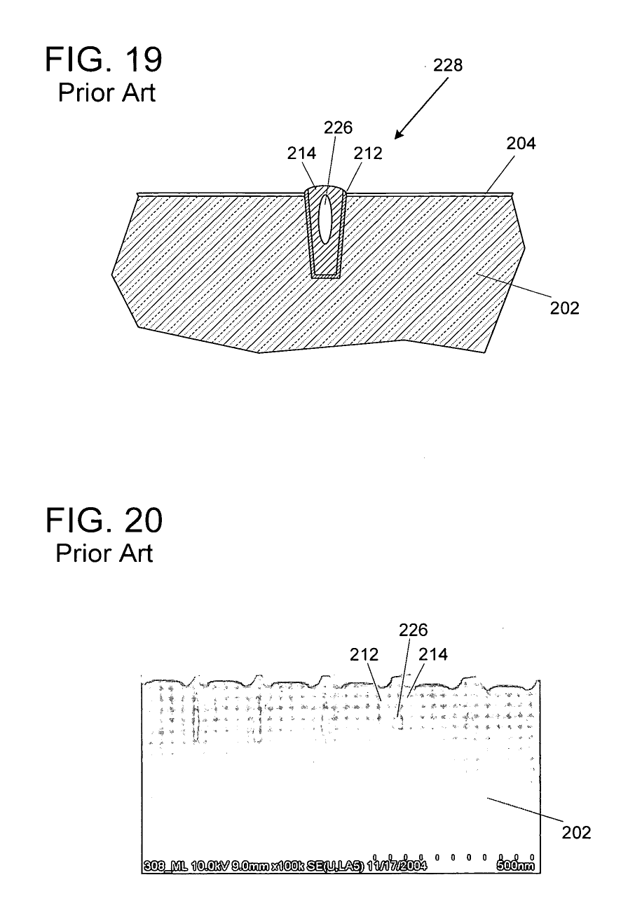

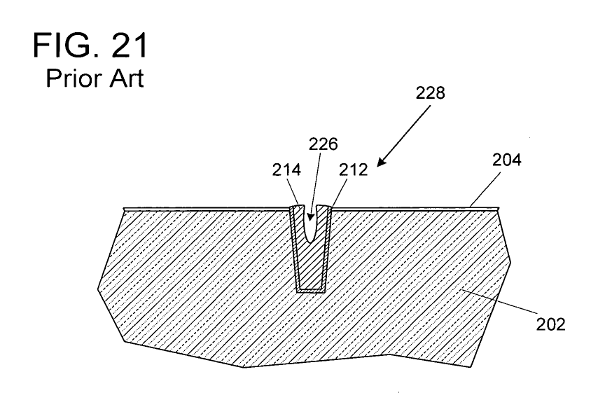

As shown in FIG. 8, any dielectric material 142 not residing within the expanded bottom trench 140 (see FIG. 5) is then removed, such as by etching or planarization by chemical mechanical polishing. The stop layer 106 acts as a barrier and/or hard stop, if chemical mechanical polishing is used, or as a etch stop, if etching is used. The stop layer 106 is then removed to form the isolation structure 150, as shown in FIG. 9, wherein the pad oxide 104 acts as a stop layer. It is noted that the removal of the stop layer 106 may also substantially remove the dielectric material 136 above a first surface 144 of the microelectronic substrate 102.

Additionally, as shown in FIG. 10, the chamber 132 of the expanded bottom trench 140 may tend to introduce voids 146 within the dielectric material 142 residing within the chamber 132. These voids 146 are generated in a controlled manner and may reduce undesirable compressive stress that the isolation generates on the silicon diffusion area. Less compressive stress from the isolation structure 140 results in transistors with higher mobility for both NMOS (x and y directions) and PMOS (y direction) devices, which translates into higher switching speed, as will be understood by those skilled in the art. The voids 146 that are introduced are acceptable because they are relatively far from the microelectronic substrate first surface 144 and, thus, will not have the potential of surfacing and creating issues with regard to topography and/or shorting, as previously discussed.

It is, of course, understood that although the description of the present invention is primarily focused on the fabrication of trench isolation structures, the teachings and principles of the present invention are not so limited and can be applied to a variety of isolation structures and a variety of via and trench filling processes.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An isolation structure, comprising:
a microelectronic substrate having a first surface;
a trench extending from said microelectronic substrate first surface into said microelectronic substrate, said trench having at least one sidewall and a trench opening proximate said microelectronic substrate first surface;
a chamber formed within said microelectronic substrate at an end of said trench opposing said trench opening; and
a dielectric material disposed within said chamber and said trench.

2. The isolation structure of claim 1, further including at least one sidewall spacer abutting said at least one trench sidewall.

3. The isolation structure of claim 1, wherein said dielectric material comprises silicon oxide.

4. The isolation structure of claim 1, wherein a width of said chamber is greater than a width of said trench proximate a bottom of said trench.

5. The isolation structure of claim 1, wherein said chamber includes a substantially arcuate shaped portion opposing said trench opening.

6. A method of forming an isolation structure, comprising:
providing a microelectronic substrate having a first surface;
forming a trench extending from said microelectronic substrate first surface into said microelectronic substrate, said trench having at least one sidewall and a trench opening proximate said microelectronic substrate first surface;
forming a chamber within said microelectronic substrate at an end of said trench opposing said trench opening; and
depositing a dielectric material within said chamber and said trench.

7. The method of claim 6, wherein forming said a chamber within said microelectronic substrate comprises:
depositing a trench sidewall spacer on said at least one trench sidewall and a bottom of said trench;
removing a portion of said trench sidewall spacer abutting said trench bottom to expose a portion of said microelectronic substrate; and
etching said exposed microelectronic substrate to form said chamber.

8. The method of claim 7, wherein removing a portion of said trench sidewall spacer abutting said trench bottom comprises exposing said trench sidewall spacer to an anisotropic etch.

9. The method of claim 7, wherein providing a microelectronic substrate comprises providing a silicon-containing microelectronic substrate.

10. The method of claim 9, wherein etching said exposed microelectronic substrate comprises etching said exposed microelectronic substrate with a selective isotropic silicon etch.

11. The method of claim 10, wherein etching said exposed microelectronic substrate to a selective isotropic silicon etch comprises etching said exposed microelectronic substrate with a plasma etch.

12. An isolation structure formed by a method, comprising:
providing a microelectronic substrate having a first surface;
forming a trench extending from said microelectronic substrate first surface into said microelectronic substrate, said trench having at least one sidewall and a trench opening proximate said microelectronic substrate first surface;
forming a chamber within said microelectronic substrate at an end of said trench opposing said trench opening; and
depositing a dielectric material within said chamber and said trench.

13. The isolation structure of claim 12, wherein forming said a chamber within said microelectronic substrate comprises:
depositing a trench sidewall spacer on said at least one trench sidewall and a bottom of said trench;
removing a portion of said trench sidewall spacer abutting said trench bottom to expose a portion of said microelectronic substrate; and
etching said exposed microelectronic substrate to form said chamber.

14. The isolation structure of claim 13, wherein removing a portion of said trench sidewall spacer abutting said trench bottom comprises exposing said trench sidewall spacer to an anisotropic etch.

15. The isolation structure of claim 13, wherein providing a microelectronic substrate comprises providing a silicon-containing microelectronic substrate.

16. The isolation structure of claim 15, wherein etching said exposed microelectronic substrate comprises etching said exposed microelectronic substrate with a selective isotropic silicon etch.

17. The isolation structure of claim 16, wherein etching said exposed microelectronic substrate with a selective isotropic silicon etch comprises etching said exposed microelectronic substrate with a plasma etch.
